(19) United States
(12) Patent Application Publication
(10) Pub. No.: US 2018/0171476 A1
(43) Pub. Date: Jun. 21, 2018

(54) METHODS AND APPARATUS FOR SELECTIVE REMOVAL OF SELF-ASSEMBLED MONOLAYERS USING LASER ANNEALING

(71) Applicant: Applied Materials, Inc., Santa Clara, CA (US)

(72) Inventors: Ludovic GODET, Sunnyvale, CA (US); Christine Y. OUYANG, Santa Clara, CA (US)

(21) Appl. No.: 15/449,891

(22) Filed: Mar. 3, 2017

Related U.S. Application Data
(60) Provisional application No. 62/437,438, filed on Dec. 21, 2016.

(51) Int. Cl. C23C 16/455; C23C 16/56; C23C 16/48; H01L 21/02; H01L 21/311; H01L 21/768; H01L 21/67

(52) U.S. Cl. CPC C23C 16/45527; C23C 16/45544; C23C 16/56; C23C 16/483; H01L 21/67167; H01L 21/311; H01L 21/76825; H01L 21/31127; H01L 21/0228

(57) ABSTRACT

Implementations described herein relate to selective removal processes. More specifically, laser thermal processing is utilized to selectively remove a self-assembled monolayer (SAM) material from a portion of a substrate. In one example, laser thermal processing may be utilized to selectively remove SAM materials from a metallic material layer preferentially to a dielectric material layer. Other implementations provide for a substrate process apparatus which includes a pre-clean chamber, a SAM deposition chamber, a laser thermal process chamber, an atomic layer deposition (ALD) chamber, and a post-process chamber all disposed about a central process chamber.

### CROSS-REFERENCE TO RELATED APPLICATIONS

This application claims benefit of U.S. Provisional Patent Application No. 62/437,438, filed Dec. 21, 2016, the entirety of which is herein incorporated by reference.

### BACKGROUND

### Field

Implementations of the present disclosure generally relate to techniques for selective deposition and removal of materials on a substrate. More specifically, implementations described herein relate to selective removal of self-assembled monolayers (SAMs) using laser annealing.

### Description of the Related Art

Reliably producing sub-half micron and smaller features is one of the key technology challenges for next generation very large scale integration (VLSI) and ultra large scale integration (ULSI) of semiconductor devices. However, as the limits of circuit technology are pushed, the shrinking dimensions of VLSI and ULSI technology have placed additional demands on processing capabilities.

As circuit densities increase for next generation devices, the widths of interconnects, such as vias, trenches, contacts, gate structures and other features, as well as the dielectric materials therebetween, decrease to 45 nm and 32 nm dimensions and beyond. In order to enable the fabrication of next generation devices and structures, three dimensional (3D) stacking of features in semiconductor chips is often utilized. In particular, fin field effect transistors (FinFETs) are often utilized to form three dimensional (3D) structures in semiconductor chips. By arranging transistors in three dimensions instead of conventional two dimensions, multiple transistors may be placed in the integrated circuits (ICs) very close to each other. As circuit densities and stacking increase, the ability to selectively deposit subsequent materials on previously deposited materials gains importance.

Self-assembled monolayers (SAMs) may be utilized as a masking material to improve subsequent material deposition selectivity. SAMs are generally surface chemistry dependent and can be formed preferentially on various materials. However, SAMs may occasionally form on undesired materials or portions of a substrate. When SAMs are formed non-preferentially, subsequent deposition processes are negatively impacted and the advantageous masking properties commonly associated with SAMs are negated to a degree.

Thus, there is a need for improved selective removal of SAMs.

### SUMMARY

In one implementation, a substrate processing apparatus is provided. The apparatus includes a transfer chamber, a pre-clean chamber coupled to the transfer chamber, a self-assembled monolayer (SAM) deposition chamber coupled to the transfer chamber adjacent the pre-clean chamber, and a laser thermal process chamber coupled to the transfer chamber adjacent the SAM deposition chamber. The apparatus also includes an atomic layer deposition (ALD) chamber coupled to the transfer chamber adjacent the laser thermal process chamber and a SAM material removal chamber coupled to the transfer chamber adjacent the ALD chamber.

In another implementation, a substrate processing apparatus is provided. The apparatus includes a vacuum transfer chamber, a pre-clean chamber coupled to the vacuum transfer chamber, a SAM deposition chamber coupled to the vacuum transfer chamber, and a laser thermal process chamber coupled to the vacuum transfer chamber. The apparatus also includes an ALD chamber coupled to the transfer chamber, a SAM material removal chamber coupled to the transfer chamber, and a robot disposed in the vacuum transfer chamber. The robot is also in operable communication with each of the pre-clean chamber, the SAM deposition chamber, the laser thermal process chamber, the ALD chamber, and the SAM material removal chamber under a vacuum environment.

In yet another implementation, a substrate processing method is provided. The method includes delivering a substrate having materials with different absorption coefficients formed thereon to a first process chamber and forming SAM materials on a first material layer of the substrate preferentially to a second material layer of the substrate in the first process chamber. The substrate is transferred to a second process chamber and exposed to layer thermal energy to remove the SAM materials from the second material layer and the substrate is transferred to a third process chamber. In the third process chamber, an atomic layer deposition process is utilized to deposit materials of the second material layer preferentially to the first material layer.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope, may admit to other equally effective implementations.

FIG. 1 illustrates a schematic, plan view of a cluster tool apparatus according to one implementation described herein.

FIG. 2 illustrates a schematic view of a laser process apparatus according to implementations described herein.

FIG. 3 illustrates a schematic view of a laser process system according to implementations described herein.

FIG. 4 illustrates operations of a method according to implementations described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Implementations described herein relate to apparatus and methods for processing a substrate. In one implementation, a cluster tool apparatus is provided having a transfer chamber and a pre or post clean chamber, a self-assembled monolayer (SAM) deposition chamber, a laser thermal process chamber, an atomic layer deposition (ALD) chamber, and a SAM removal chamber disposed about the transfer chamber. A substrate may be processed by the cluster tool and transferred between the pre or post clean chamber, the SAM deposition chamber, the laser thermal process chamber, the ALD chamber, and the SAM removal chamber. Transfer of the substrate between each of the chambers may be facilitated by the transfer chamber which houses a transfer robot.

Implementations described herein also relate to methods for selective removal of SAMs from desired regions of a substrate. In one implementation, SAMs which are undesirably formed on a metallic portion of a substrate are removed via laser thermal processing preferentially to SAMs formed on a dielectric portion of the substrate. The laser thermal processing utilizes the absorption coefficient difference between different materials, such as metal and dielectric materials, to initiate and facilitate removal of SAMs from undesired portions and materials of the substrate.

As utilized herein, “self-assembled monolayer” (SAM) generally refers to a layer of molecules that are attached (e.g., by a chemical bond) to a surface and that have adopted a preferred orientation with respect to that surface and even with respect to each other. The SAM typically includes an organized layer of amphiphilic molecules in which one end of the molecule, the “head group” shows a specific, reversible affinity for a substrate. Selection of the head group will depend on the application of the SAM, with the type of SAM compounds based on the substrate utilized. Generally, the head group is connected to an alkyl chain in which a tail or “terminal end” can be functionalized, for example, to vary wetting and interfacial properties. The molecules that form the SAM will selectively attach to one material over another material (e.g., metal vs. dielectric) and if of sufficient density, can successfully enable subsequent deposition allowing for selective deposition on materials not coated with the SAM.

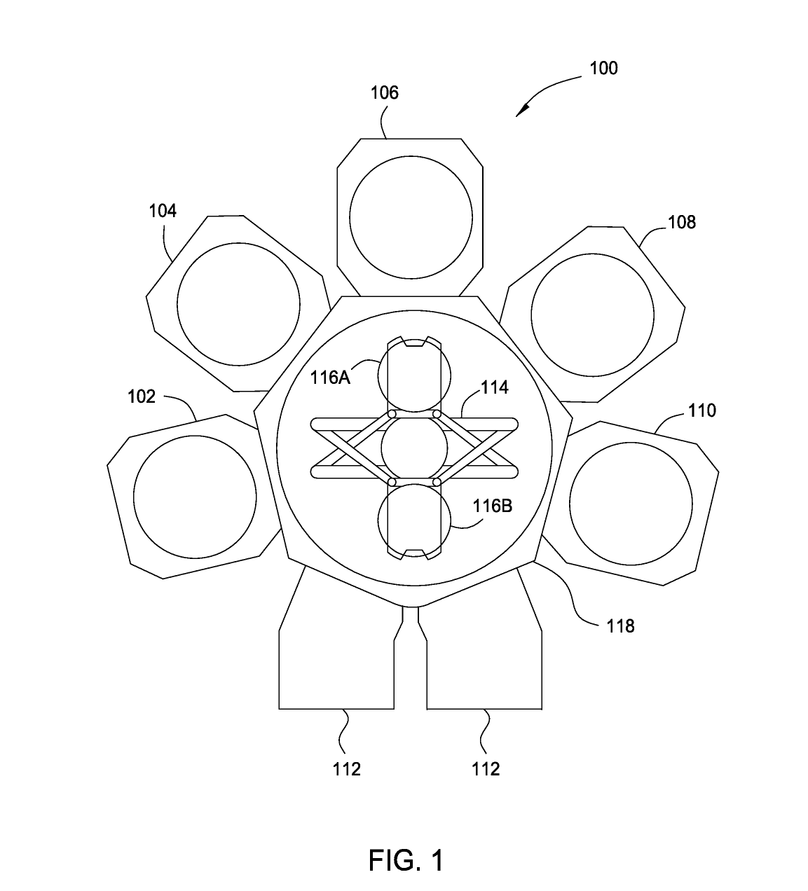

FIG. 1 illustrates a schematic, plan view of a cluster tool apparatus 100 according to implementations described herein. Examples of suitable apparatus which may be utilized in accordance with the implementations described herein include the CENTURA® and ENDURA® platforms, both of which are available from Applied Materials, Inc., Santa Clara, Calif. It is contemplated that other suitably configured apparatus from other manufacturers may also be advantageously utilized in accordance with the implementations described herein. In addition, the PRODUCER® platform, also available from Applied Materials, Inc., Santa Clara, Calif., having dual-chamber capability may be advantageously employed according to the implementations described herein. Further, the RAIDER® platform, also available from Applied Materials, Inc., Santa Clara, Calif., may also be utilized in accordance with the implementations described herein.

The apparatus 100 includes a plurality of process chambers 102, 104, 106, 108, 110, a transfer chamber 118, and load lock chambers 112. Each of the process chambers 102, 104, 106, 108, 110 is coupled to the transfer chamber 118. In one implementation, the process chamber 104 is disposed adjacent the process chamber 102. In one implementation, the process chamber 106 is disposed adjacent the process chamber 104. In one implementation, the process chamber 108 is disposed adjacent the process chamber 106. In one implementation, the process chamber 110 is disposed adjacent the process chamber 108. While the process chambers 102, 104, 106, 108, 110 are illustrated as having a specific arrangement with respect to one another, it is contemplated that the process chambers 102, 104, 106, 108, 110 may be disposed about the transfer chamber 118 with any desirable arrangement.

Each process chamber represents, and may be used for, a different stage or phase of substrate processing. In one implementation, the process chamber 102 is a pre-clean chamber. In one implementation, the process chamber 102 prepares surfaces of a substrate being processed for subsequent processing. In various examples, the process chamber 102 may remove substrate defects which result from air exposure, remove native oxide layers, and/or remove sacrificial layers disposed on a surface of the substrate to be treated by SAM, laser, ALD processing, thermal, or other type of processing. In another example, the process chamber 102 is utilized for substrate surface functionalization. In this example, surface terminal groups may be modified to enable, assist, or prevent the formation of a SAM on the substrate, depending upon the desired implementation.

Specific examples of surface treatment which may be performed by the process chamber 102 include metal oxide removal via plasma treatment, surface hydroxyl functionalization using H₂/O₂ plasma treatment or water vapor exposure, residual removal, photoresist removal, sputter cleaning, radical cleaning, and/or oxide removal using a SICONI® process or the like. The SICONI® process is available from Applied Materials, Inc., Santa Clara, Calif. One example of a pre-clean chamber that may be utilized as the process chamber 102 is the AKTIV® pre-clean chamber also available from Applied Materials, Inc., Santa Clara, Calif. It is contemplated that other similarly configured process chambers and treatment processes from other manufacturers may be advantageously implemented in accordance with the implementations described herein.

More specifically, the process chamber 102 is utilized to enable selective area SAM adsorption. For example, an octadecyltrichlorosilane (ODTCS) SAM may bond to a dielectric or metal oxide material preferentially to a metal or Si—H terminated surface, assuming desirable conditions are present. The process chamber 102 is utilized to remove the metal oxide or native oxide to form an exposed metal surface or Si—H terminated surface which prohibits or substantially prohibits SAM adsorption.

In one implementation, the process chamber 104 is a SAM deposition chamber. The process chamber 104 is configured to enable SAM molecules to selectively adsorb to one material of a substrate preferentially to another material of the substrate. The SAM molecules may be deposited on the substrate by various methods, including vapor phase deposition, spin coating, stamping, and liquid immersion techniques, among others. The selective adsorption is generally controlled by the reactivity of the SAM molecule headgroup and the surface termination characteristics/functional groups disposed on the substrate surface. For example, a substrate having exposed SiO₂ and Cu materials which are exposed to the same SAM treatment process will result in the SAM molecules selective to metals bonding to the Cu preferentially and substantially no adsorption on the SiO₂ material. The resulting SAM material has a high water contact angle (i.e. greater than about 105°) which indicates the formation of a dense SAM.

Examples of SAM materials which may be utilized include the materials described hereinafter, including combinations, mixtures, and grafts thereof, in addition to other SAM materials having characteristics suitable for blocking deposition of subsequently deposited materials in a semiconductor fabrication process. In one implementation, the SAM materials may be carboxylic acid materials, such as methylcarboxylic acids, ethylcarboxylic acids, propylcarboxylic acids, butylcarboxylic acids, pentylcarboxylic acids, hexylcarboxylic acids, heptylcarboxylic acids, octylcarboxylic acids, nonylcarboxylic acids, decylcarboxylic acids, undecylcarboxylic acids, dodecylcarboxylic acids, tridecylcarboxylic acids, tetradecylcarboxylic acids, pentadecylcarboxylic acids, hexadecylcarboxylic acids, heptadecylcarboxylic acids, octadecylcarboxylic acids, and nonadecylcarboxylic acids.

In another implementation, the SAM materials may be phosphonic acid materials, such as methylphosphonic acid, ethylphosphonic acid, propylphosphonic acid, butylphosphonic acid, pentylphosphonic acid, hexylphosphonic acid, heptylphosphonic acid, octylphosphonic acid, nonylphosphonic acid, decylphosphonic acid, undecylphosphonic acid, dodecylphosphonic acid, tridecylphosphonic acid, tetradecyphosphonic acid, pentadecylphosphonic acid, hexadecylphosphonic acid, heptadecylphosphonic acid, octadecylphosphonic acid, and nonadecylphosphonic acid.

In another implementation, the SAM materials may be thiol materials, such as methanethiol, ethanethiol, propanethiol, butanethiol, pentanethiol, hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, octadecanethiol, and nonadecanethiol.

In another implementation, the SAM materials may be silylamine materials, such as tris(dimethylamino)methylsilane, tris(dimethylamino)ethylsilane, tris(dimethylamino)propylsilane, tris(dimethylamino)butylsilane, tris(dimethylamino)pentylsilane, tris(dimethylamino)hexylsilane, tris(dimethylamino)heptylsilane, tris(dimethylamino)octylsilane, tris(dimethylamino)nonylsilane, tris(dimethylamino)decylsilane, tris(dimethylamino)undecylsilane tris(dimethylamino)dodecylsilane, tris(dimethylamino)tridecylsilane, tris(dimethylamino)tetradecylsilane, tris(dimethylamino)pentadecylsilane, tris(dimethylamino)hexadecylsilane, tris(dimethylamino)heptadecylsilane, tris(dimethylamino)octadecylsilane, and tris(dimethylamino)nonadecylsilane.

In another implementation, the SAM materials may be chlorosilane materials, such as methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane, and nonadecyltrichlorosilane.

In another implementation, the SAM materials may be oxysilane materials, such as methyltrimethoxysilane, methyltriethoxysilane, ethyltrimethoxysilane, ethyltriethoxysilane, propyltrimethoxysilane, propyltriethoxysilane, butyltrimethoxysilane, butyltriethoxysilane, pentyltrimethoxysilane, pentyltriethoxysilane, hexyltrimethoxysilane, hexyltriethoxysilane, heptyltrimethoxysilane, heptyltriethoxysilane, octyltrimethoxysilane, octyltriethoxysilane, nonyltrimethoxysilane, nonyltriethoxysilane, decyltrimethoxysilane, decyltriethoxysilane, undecyltrimethoxysilane, undecyltrethoxysilane, dodecyltrimethoxysilane, dodecyltriethoxysilane, tridecyltrimethoxysilane, tridecyltriethoxysilane, tetradecyltrimethoxysilane, tetradecyltriethoxysilane, pentadecyltrimethoxysilane, pentadecyltriethoxysilane, hexadecyltrimethoxysilane, hexadecyltroethoxysilane, heptadecyltrimethoxysilane, heptadecyltriethoxysilane, octadecyltrimethoxylsilane octadecyltriethoxysilane, nonadecyltrimethoxysilane, and nonadecyltriethoxysilane.

In another implementation, the SAM molecules 230 may have a fluorinated R group, such as (1,1,2,2-perfluorodecyl)trichlorosilane, trichloro(1,1,2,2-perflrorooctyl)silane, (trideca-fluoro-1,1,2,2-tetrahydrooctyl)trichlorosilane, (tridecafluoro-1,1,2,2-tetrahydro-octyl)triethoxysilane, (tridecafluoro-1,1,2,2-tetrahydrooctyl)methyldichlorosilane, (tridecafluoro-1,1,2,2-tetrahydrooctyl)dimethylchlorosilane, and (heptadecafluoro-1,1,2,2-tetrahydrodecyl)trichlorosilane, among others. It is contemplated that combinations and mixtures of the aforementioned materials are within the scope of this disclosure.

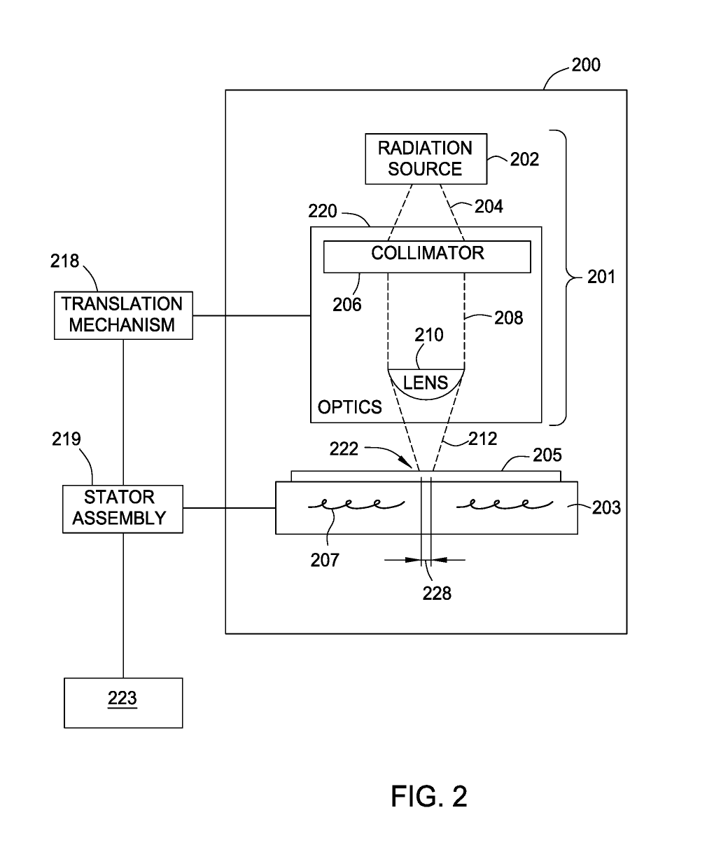

In one implementation, the process chamber 106 is a laser thermal process chamber. In one implementation, the process chamber 106 is a millisecond laser annealing chamber, which is described in greater detail with regard to FIG. 2. For example, the process chamber 106 may be the VANTAGE® ASTRA™ tool available from Applied Materials, Inc., Santa Clara, Calif. It is also contemplated that other suitably configured laser processing tools from other manufacturers may be advantageously utilized according to the implementations described herein. In another implementation, the process chamber 106 is a nanosecond laser annealing chamber. In another implementation, the process chamber 106 is a picosecond laser annealing chamber. By utilizing the fast thermal ramping properties of laser thermal processes in combination with the absorption coefficient differences between different material layers on the substrate, SAM materials may be selectively removed from desired portions of the substrate.

In one implementation, the process chamber 108 is an ALD chamber. The process chamber 108 is configured to enable deposition on surfaces of the substrate not covered by the SAM materials. For example, ALD materials generally do not form on surfaces which have a water contact angle greater than about 105°, such as greater than about 110°. Accordingly, the ALD process may be selectively deposited on a desired material of the substrate by utilizing the SAM material to improve the selectivity of deposition. Suitable examples of ALD process chambers include the CENTURA® or ENDURA® ALD process chambers or the OLYMPIA® ALD process chamber, all of which are available from Applied Materials, Inc., Santa Clara, Calif. It is contemplated that other suitably configured apparatus from other manufacturers may also be advantageously implemented according to the implementations described herein.

In one implementation, the process chamber 110 is a SAM removal or post-clean chamber. The process chamber 110 may be utilized to remove SAM materials from the substrate either before or after ALD processing in the process chamber 108. In one implementation, the SAM materials are removed from the substrate by the process chamber 110 after ALD deposition in the process chamber 108.

In one implementation, the process chamber 110 is a thermal process bake chamber. In this implementation, the process chamber 110 includes a heated pedestal which is capable of heating a substrate to a temperature of greater than about 350° C. to volatilize SAM materials from the surface of the substrate. In another implementation, the process chamber 110 is a plasma process chamber. In this implementation, a plasma is generated to remove SAM materials from the substrate. The plasma may be a capacitively coupled plasma, an inductively coupled plasma, a microwave source plasma, or a helicon source plasma or the like. The process chamber 110 may utilize any of the aforementioned plasma generation sources to generate a plasma which removes SAM materials from the substrate. In one implementation, a hydrogen plasma is generated by the process chamber 110 to remove the SAM materials.

In another implementation, the process chamber 110 is a rapid thermal process chamber. In this implementation, the process chamber 110 is configured to quickly heat the substrate to volatilize SAM materials from the surface of the substrate. In one example, the process chamber 110 may be a lamp based rapid thermal process chamber. Examples of suitable process chambers include the VULCAN™ and RADIANCE® tools available from Applied Materials, Inc., Santa Clara, Calif. It is contemplated that suitably configured apparatus from other manufacturers may also be advantageously implemented according to the implementations described herein.

The transfer chamber 118, which enables transfer of the substrate between the process chambers 102, 104, 106, 108, 110 houses a transfer robot 114 therein. The transfer robot 114 may be a single blade robot or a dual blade robot as illustrated. The dual blade robot 114 has a pair of substrate transport blades 116A, 116B attached to distal ends of a pair of extendable arms. The blades 116A, 116B are used to support and carry individual substrates between the chambers 102, 104, 106, 108. The transfer chamber 118 is also maintained under vacuum or an otherwise reduced oxygen environment. In one example, the transfer robot 114 is in operable communication with each of the process chambers 102, 104, 106, 108, 110 under a vacuum environment. In one implementation, the robot transfers substrates between one or more of the process chambers 102, 104, 106, 108, 110 under vacuum. Thus, the probability of substrate oxidation during transfer is reduced or eliminated.

Air exposure of the substrate between SAM treatment and ALD treatment is potentially detrimental to the effectiveness of the SAM material for ALD blocking and transferring the substrate between the process chamber 104 and the process chamber 106 in-situ provides for improved processing performance, such as higher deposition selectivity. In addition, it may be desirable to perform cyclic SAM and ALD processes, thus, the transfer chamber enables efficient transfer of substrates between the process chambers 104, 106, 108 while also improving the processing performance by preventing exposure of the substrate to an ambient air environment.

FIG. 2 illustrates a schematic view of a laser thermal process chamber 200 with a radiation module 201, according to implementations described herein. In one implementation, the laser thermal process chamber 200 is the process chamber 106. The process chamber 200 shown in FIG. 2 includes a substrate support 203 and a translation mechanism 218. The substrate support 203 may include a heat source 207, such as a resistive heater or the like, to heat the substrate independently of a radiation source 202. The radiation module 201 generally includes the radiation source 202 and focusing optics 220 disposed between the radiation source 202 and the substrate support 203.

The radiation source 202 is a laser source capable of emitting continuous waves of electromagnetic radiation or pulsed emissions of electromagnetic radiation. In certain implementations, a single radiation source 202 is utilized to generate a laser beam. In other implementations, multiple radiation sources 202 are utilized to generate the laser beam. In one implementation, the radiation source 202 comprises a plurality of fiber lasers. Alternatively, the radiation source 202 may be a non-laser radiation source, such as a flash lamp, a halogen lamp, a light emitting diode source, or the like. For example, a non-laser low incidence flux source may be a suitable example of the radiation source 202.

Generally, the radiation source 202 is utilized to heat the substrate during a selective SAM material removal process. More specifically, the radiation source 202 is utilized to induce a temperature increase in a desired region of the surface of a substrate 205 relative to another region without damaging the underlying material layers. After exposure of the substrate 205 to the radiation source 202, the substrate 205 may be laterally conductively cooled by the bulk of the substrate. However, it is contemplated that any combination of processing techniques and temperatures may be utilized to process the substrate 205 in various different manners.

The radiation emitted from the radiation source 202 may be absorbed at or near the surface of the substrate 205. In one implementation, an anneal depth of the radiation into the substrate 205 may be between about 1 nm and about 50 nm. The radiation is also emitted from the radiation source 202 at a wavelength within the range at which the substrate 205 absorbs radiation. Generally, for a silicon containing substrate, the radiation wavelength may be between about 190 nm and about 950 nm, for example, about 810 nm.

Alternatively, a high power UV laser may be utilized as the radiation source 202. In one implementation, the substrate 205 has dielectric regions with SAM materials formed thereon and metallic regions which may undesirably have SAM materials formed thereon. In one example, the entire substrate surface is exposed to radiation from the radiation source 202 and the absorption coefficient delta between the dielectric materials and metallic materials induces removal of the SAM materials from the metallic regions.

The radiation source 202 may be capable of emitting radiation continuously for an amount of time greater than about 1 second, such as greater than about 10 seconds, for example, greater than about 15 seconds. Alternatively, the radiation source 202 may be capable of emitting pulses of radiation for an amount of time greater than about 1 second, such as greater than about 10 seconds, for example, greater than about 15 seconds. A dwell time of the radiation at a single point on the substrate 205 may be less than 1 second, for example between 1 millisecond and several hundred milliseconds. In another example, the dwell time of the radiation at a single point on the substrate 205 may be between several nanoseconds and several hundred nanoseconds. In another example, the dwell time of the radiation at a single point on the substrate 205 may be between several picoseconds and several hundred picoseconds.

The radiation source 202 may include multiple laser diodes, each of which produces uniform and spatially coherent light at substantially the same wavelength. The power of the laser diode(s) may be within the range of between about 0.5 kW and about 50 kW, for example about 5 kW.

The focusing optics 220 may include one or more collimators 206 to collimate radiation 204 from the radiation source 202 into a substantially parallel beam. The collimated radiation 208 may then be focused by at least one lens 210 into a line of radiation 212 at an upper surface 222 of the substrate 205. The term “line of radiation” as used herein is intended to be representative of the spatial distribution of the radiation 212 at the upper surface 222 of the substrate 205. It is contemplated the spatial distribution of the radiation 212 may be shaped like a line or ribbon, a spot or plurality of spots, and the like. Generally, the substrate 205 may be a circular substrate having a diameter of about 200 mm, about 300 mm, or about 450 mm. The line of radiation 212 may extend across the substrate 205 with a width 228 of between about 3 μm and about 500 μm.

Generally, the length of the line of radiation 212 may be greater than the width 228. In one implementation, the line of radiation 212 may linearly traverse the substrate 205 such that the line of radiation 212 is substantially perpendicular to the direction of movement of the substrate 205, i.e. the line of radiation 212 remains parallel to a fixed line or chord of the substrate 205 that is perpendicular to the direction of substrate movement. In one implementation, the line of radiation 212 may be a Gaussian laser spot. In this implementation, one or more Gaussian laser spots may be generated (i.e. by multiple radiation sources such as fiber lasers) in the shape of a ribbon (line).

The lens 210 may be any suitable lens, or series of lenses, suitable for forming the desired shape of the line of radiation 212. In one implementation, the lens 210 may be a cylindrical lens. Alternatively, the lens 210 may be one or more concave lenses, convex lenses, plane mirrors, concave mirrors, convex mirrors, refractive lenses, diffractive lenses, Fresnel lenses, gradient index lenses, or the like. Generally, the lens 210 may be configured to influence a radial or diametric power distribution of the line of radiation 212 from the origin to the circumference of the substrate 205.

The power distribution of the line of radiation 212 may be between about 10 kW/cm² and about 200 kW/cm². In one implementation, an equal power distribution along the line of radiation 212 is substantially constant. In this implementation, the substrate's exposure to the radiation 212 may be modulated by the shape or spatial distribution of the radiation 212 at the upper surface 222 of the substrate 205. It is contemplated that the substrate 140 may be heated to temperatures up to about 1000° C. by the radiation module 201 and the pedestal 203 (e.g. heat source 207). In one implementation, the heat source 207 in the pedestal 203 heats the substrate 205 to a temperature from about room temperature to about 300° C., for example, between about 100° C. and about 200° C. In one implementation, the substrate 205 may be heated by the radiation module 201 to a temperature between about 500° C. and about 1,000° C., such as between about 600° C. and about 700° C. The ramp-up and ramp-down rates of the radiation module 201 heating may exceed about 4,000,000° C./sec.

By utilizing laser heating of the substrate 205 in this manner, different materials, such as dielectric and metallic materials disposed on the substrate 205, will be exposed to the same amount of radiation. However, due to the absorption coefficient deltas between the various materials, selective removal of SAM materials may be achieved. It is contemplated that as little as a 20° C. difference in surface temperature between different materials can facilitate removal of SAM materials.

For example, metallic materials such as copper, nickel, ruthenium, etc., which generally have a higher absorption coefficient when compared to dielectric materials, may heat more quickly than dielectric materials and cause volatilization of SAM materials from the surface of metallic regions of the substrate 205. Accordingly, SAM materials may be selectively removed from undesired regions of the substrate 205. Moreover, the laser thermal processing may be configured to leave the surfaces of the different materials on the substrate 205 undamaged due to the short laser dwell time and fast ramp rates associated with the laser thermal processing described herein.

A stator assembly 219 may be configured to rotate the substrate 205 within the chamber 200. The stator assembly 219 generally rotates the pedestal 203 to impart a rotational velocity to the substrate 205 disposed thereon. In certain implementations, the stator assembly 118 may be configured to rotate the substrate 205 at between about 10 revolutions per minute and about 500 revolutions per minute, such as between about 200 revolutions per minute and about 300 revolutions per minute, for example, between about 230 revolutions per minute and about 250 revolutions per minute.

A translation mechanism 218, such as a stepper motor, may be coupled to the radiation module 201 in one implementation. In this implementation, the translation mechanism 218 may be configured to move the radiation module 201, or various components thereof, relative to the upper surface 222 of the substrate 205. For example, the translation mechanism 218 may move the line of radiation 212 from the center of the substrate 140 towards the edge of the substrate 140. Alternatively, the translation mechanism 218 may move the line of radiation 212 from the edge of the substrate 205 towards the center of the substrate 205. In one implementation, the translation mechanism 218 may be configured to raster the line of radiation 212. In this implementation, the raster cycle may be performed at greater than about 1 Hz, such as greater than about 1 kHz. In addition, the translation mechanism 218 and the stator assembly 219 may be in electrical communication with each other and actions performed by either the translation mechanism 218 and/or the stator assembly 219 may be controlled by a controller 223.

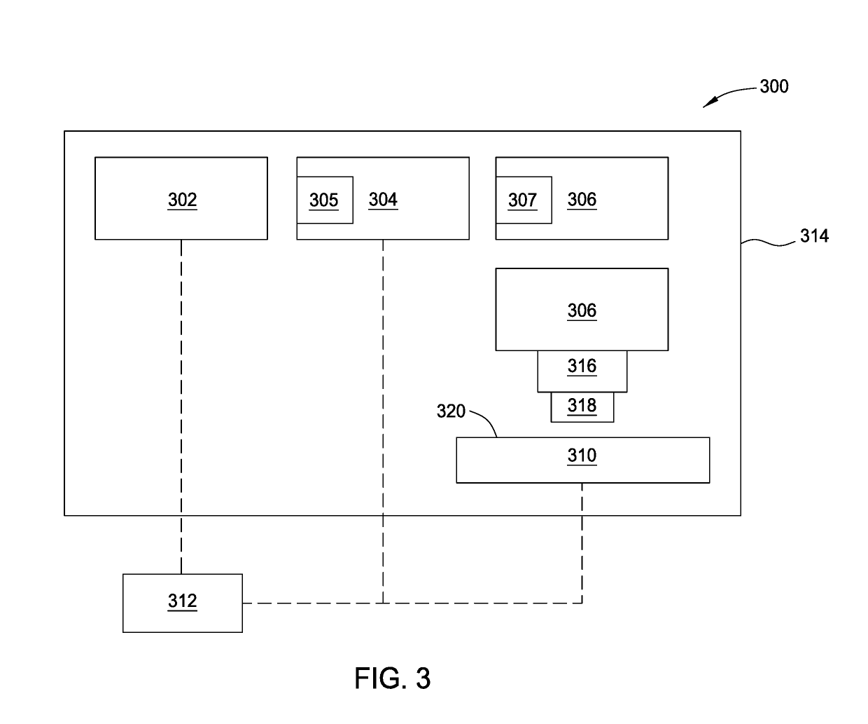

FIG. 3 is a schematic view of a system 300 for laser processing of substrates according to another implementation. For example, the system 300 may be the process chamber 106 in certain implementations. The system 300 includes an energy module 302 that has a plurality of pulsed laser sources producing a plurality of laser pulses and a pulse control module 304 that combines individual laser pulses into combination laser pulses, and that controls intensity, frequency characteristics, and polarity characteristics of the combination laser pulses. The system 300 also includes a pulse shaping module 306 that adjusts the temporal profile of the pulses of the combined laser pulses and a homogenizer 308 that adjusts the spatial energy distribution of the pulses, overlapping the combination laser pulses into a single uniform energy field. Additionally, the system 300 includes an aperture member 316 that removes residual edge non-uniformity from the energy field and an alignment module 318 that allows precision alignment of the laser energy field with a substrate disposed on a substrate support 310. A controller 312 is coupled to the energy module 302 to control production of the laser pulses, the pulse control module 304 to control pulse characteristics, and the substrate support 310 to control movement of the substrate with respect to the energy field. An enclosure 314 typically encloses the operative components of the system 300.

The lasers may be any type of laser capable of forming short pulses, for example duration less than about 100 nsec., of high power laser radiation. Typically, high modality lasers having over 500 spatial modes with M² greater than about 30 are used. Solid state lasers such as Nd:YAG, Nd:glass, titanium-sapphire, or other rare earth doped crystal lasers are frequently used, but gas lasers such as excimer lasers, for example XeCl₂, ArF, or KrF lasers, may be used. The lasers may be switched, for example by q-switching (passive or active), gain switching, or mode locking. A Pockels cell may also be used proximate the output of a laser to form pulses by interrupting a beam emitted by the laser. In general, lasers usable for pulsed laser processing are capable of producing pulses of laser radiation having energy content between about 100 mJ and about 10 J with dwell time between about 1 nsec and about 100 μsec, typically about 1 J in about 8 nsec. The lasers may have wavelength between about 200 nm and about 2,000 nm, such as between about 400 nm and about 1,000 nm, for example about 532 nm.

Similar to the implementations described with regard to FIG. 2, the laser radiation may heat portions of the substrate to a temperature between about 500° C. and about 1,000° C., such as between about 600° C. and about 700° C. However, it is contemplated that other temperature ranges may be utilized if the materials on the substrate exposed to the laser radiation exhibit sufficiently different absorption coefficients to enable selective removal of SAM materials preferentially from one material relative to another material (e.g. metallic relative to dielectric).

In one implementation, the lasers are q-switched frequency-doubled Nd:YAG lasers. The lasers may all operate at the same wavelength, or one or more of the lasers may operate at different wavelengths from the other lasers in the energy module 302. The lasers may be amplified to develop the power levels desired. In most cases, the amplification medium will be the same or similar composition to the lasing medium. Each individual laser pulse is usually amplified by itself, but in some implementations, all laser pulses may be amplified after combining.

A typical laser pulse delivered to a substrate is a combination of multiple laser pulses. The multiple pulses are generated at controlled times and in controlled relationship to each other such that, when combined, a single pulse of laser radiation results that has a controlled temporal and spatial energy profile, with a controlled energy rise, duration, and decay, and a controlled spatial distribution of energy non-uniformity. The controller 312 may have a pulse generator, for example an electronic timer coupled to a voltage source, that is coupled to each laser, for example each switch of each laser, to control generation of pulses from each laser.

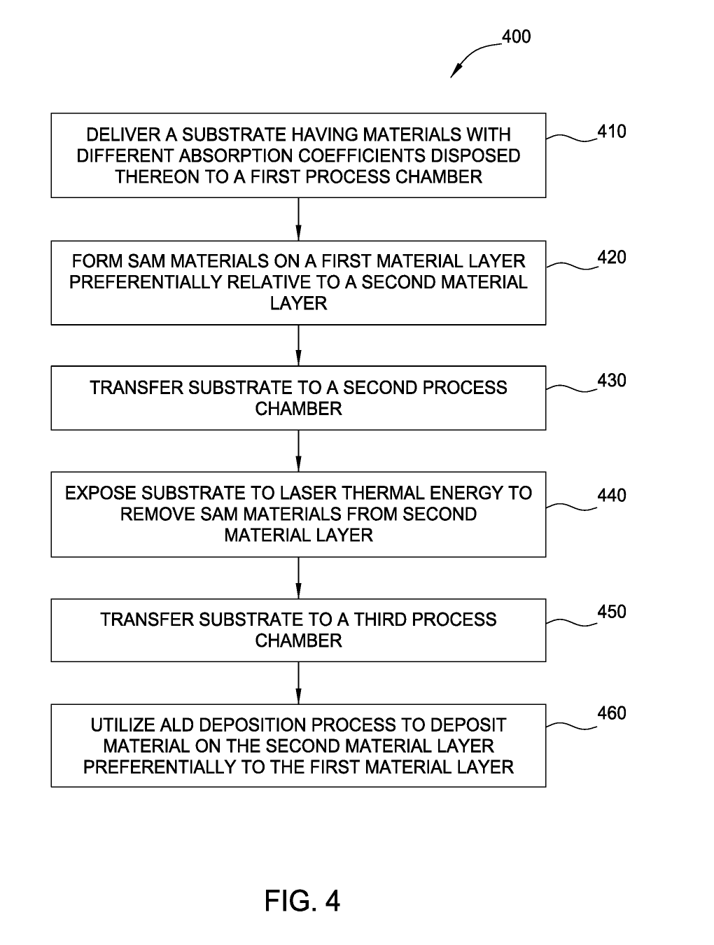

FIG. 4 illustrates operations of a method 400 according to implementations described herein. At operation 410, a substrate having materials with different absorption coefficients disposed thereon is delivered to a first process chamber. For example, the substrate may have dielectric material layers and metallic material layers disposed thereon which have different absorption coefficients. The first process chamber may be the process chamber 104. Optionally, the substrate may be pre-processed in the process chamber 102, if desired. At operation 420, SAM materials are formed on a first material layer of the substrate preferentially to a second material layer of the substrate. In one implementation, the SAM materials are formed on a dielectric material layer preferentially to a metallic material layer. However, it is contemplated that some SAM materials may be formed on the metallic material layer which will be subsequently removed in operation 440.

At operation 430, the substrate is transferred to a second process chamber, such as the process chamber 106. At operation 440, the substrate is exposed to laser thermal energy to remove the SAM material from the second material layer. As previously described, SAM materials formed on the second material layer (metallic layer) will be volatilized from the second material layer due to the relatively high absorption coefficient of the second material layer compared to the first material layer.

At operation 450, the substrate is transferred to a third process chamber, such as the process chamber 108. At operation 460, ALD deposition is utilized to deposit materials on the second material layer preferentially to the first material layer. Optionally, the substrate may be transferred to the process chamber 110 for any desired post processing.

It is also contemplated that various operations of the method 400 may be repeated or performed in a cyclic manner. For example, operations 420, 430, and 440 may be repeated in a cyclic manner any number of desirable times to prepare the substrate for subsequent ALD processing.

In summation, selective removal of SAM materials from specific materials of a substrate may be achieved according to the implementations described herein. By utilizing the properties of nano or millisecond laser annealing and the absorption coefficient differences of dielectric and metallic materials, SAM materials may be selectively removed from metallic materials while leaving the surface of the metallic material undamaged and the SAM materials remaining on the dielectric materials.

While the foregoing is directed to implementations of the present disclosure, other and further implementations of the disclosure may be devised without departing from the basic scope thereof, and the scope thereof is determined by the claims that follow.

1. A substrate processing apparatus, comprising:
a transfer chamber;
a pre-clean chamber coupled to the transfer chamber;
a self-assembled monolayer (SAM) deposition chamber coupled to the transfer chamber adjacent the pre-clean chamber;
a laser thermal process chamber coupled to the transfer chamber adjacent the SAM deposition chamber;
an atomic layer deposition (ALD) chamber coupled to the transfer chamber adjacent the laser thermal process chamber; and
a SAM material removal chamber coupled to the transfer chamber adjacent the ALD chamber.

2. The apparatus of claim 1, further comprising:
one or more load lock chambers coupled to the transfer chamber.

3. The apparatus of claim 2, wherein the load lock chambers are coupled to the transfer chamber between the pre-clean chamber and the SAM material removal chamber.

4. The apparatus of claim 1, wherein the pre-clean chamber is configured to remove oxide materials from a substrate.

5. The apparatus of claim 1, wherein the SAM deposition chamber is configured to deposit SAM materials via vapor deposition techniques.

6. The apparatus of claim 1, wherein the laser thermal process chamber is a millisecond anneal chamber.

7. The apparatus of claim 1, wherein the laser thermal process chamber is a nanosecond anneal chamber.

8. The apparatus of claim 1, wherein the laser thermal process chamber is a picosecond anneal chamber.

9. The apparatus of claim 1, wherein the laser thermal process chamber comprises a laser configured to generate a plurality of laser pulses.

10. The apparatus of claim 9, wherein the plurality of laser pulses have a wavelength of between about 190 nm and about 950 nm.

11. The apparatus of claim 1, wherein the SAM material removal chamber is a plasma chamber.

12. The apparatus of claim 1, wherein the SAM material removal chamber is thermal bake chamber having a heated pedestal disposed therein.

13. The apparatus of claim 1, wherein the SAM material removal chamber is a rapid thermal process chamber comprising lamps.

14. A substrate processing apparatus, comprising:
a vacuum transfer chamber;
a pre-clean chamber coupled to the vacuum transfer chamber
a SAM deposition chamber coupled to the vacuum transfer chamber;
a laser thermal process chamber coupled to the vacuum transfer chamber;
an ALD chamber coupled to the transfer chamber;
a SAM material removal chamber coupled to the transfer chamber; and
a robot disposed in the vacuum transfer chamber, wherein the robot is in operable communication each of the pre-clean chamber, the SAM deposition chamber, the laser thermal process chamber, the ALD chamber, and the SAM material removal chamber under a vacuum environment.

15. A substrate processing method, comprising:
delivering a substrate to a first process chamber, wherein the substrate has materials formed thereon having different absorption coefficients;
forming SAM materials on a first material layer of the substrate preferentially to a second material layer of the substrate in the first process chamber;
transferring the substrate to a second process chamber and exposing the substrate to laser thermal energy to remove the SAM materials from the second material layer; and
transferring the substrate to a third process chamber and utilizing an atomic layer deposition process to deposit materials on the second material layer preferentially to the first material layer.

16. The method of claim 15, further comprising:
transferring the substrate to a fourth process chamber and removing the SAM materials from the first material layer.

17. The method of claim 15, further comprising:
prior to delivering the substrate to the first process chamber, cleaning the substrate in a pre-clean chamber.

18. The method of claim 15, wherein the laser thermal energy is configured to generate a temperature difference between the first material layer and the second material of greater than about 20° C.

19. The method of claim 15, wherein the forming SAM materials and the exposing the substrate to laser thermal energy are repeated in a cyclic manner.

20. The method of claim 15, wherein the delivering a substrate to a first process chamber, the transferring the substrate to a second process, and the transferring the substrate to a third process chamber are performed under vacuum.
